(19) United States
(12) Patent Application Publication
(10) Pub. No.: US 2025/0293211 A1
(43) Pub. Date: Sep. 18, 2025

(54) HEAT DISSIPATION FOR STACKED INTEGRATED CIRCUIT DEVICES

(71) Applicant: QUALCOMM Incorporated, San Diego, CA (US)

(72) Inventors: Bohan YAN, San Diego, CA (US); Aniket PATIL, San Diego, CA (US); Manuel ALDRETE, Encinitas, CA (US); Nader NIKFAR, San Diego, CA (US)

(21) Appl. No.: 18/602,545

(22) Filed: Mar. 12, 2024

(51) Int. Cl. H01L 25/065; H01L 23/00; H01L 23/367; H01L 25/18

(52) U.S. Cl. CPC H01L 25/0657; H01L 23/367; H01L 24/32; H01L 25/18; H01L 2224/32225; H01L 2225/06589; H01L 2924/1436

(57) ABSTRACT

An integrated device includes a first die and a second die stacked above the first die and electrically interconnected to the first die. The integrated device also includes a conductive structure in thermal contact with a top surface of the first die and in thermal contact with a top surface of the second die. The conductive structure is configured to dissipate heat from the first die and the second die.

### FIELD

Various features relate to heat dissipation for stacked integrated circuit devices.

### DESCRIPTION OF RELATED ART

Electrical connections exist at each level of a system hierarchy. This system hierarchy includes interconnection of active devices at a lowest system level all the way up to system level interconnections at the highest level. For example, interconnect layers can connect different devices together on an integrated circuit. As integrated circuits become more complex, more interconnect layers are used to provide the electrical connections between the devices. More recently, the number of interconnect levels for circuitry has substantially increased due to the large number of devices that are now interconnected in a modern electronic device. The increased number of interconnect levels for supporting the increased number of devices involves more intricate processes.

State-of-the-art mobile application devices demand a small form factor, low cost, a tight power budget, and high electrical performance. Mobile package design has evolved to meet these divergent goals for enabling mobile applications that support resource-intensive functionality. Other devices, such as internet-of-things (IoT) and augmented reality (AR) devices share similar design goals. One technique for supporting such these design goals is to include multiple devices in a stacked integrated circuit (IC) that efficiently utilizes space within the small form factor. However, stacked IC devices, particularly those in a package-on-package (POP) configuration, may only be able to operate at full performance levels for a limited amount of time due to heat accumulation within the packages. Although a heat sink or other cooling device can be attached to a top surface of the stack to dissipate heat from the packages, the effectiveness of the heat dissipation for a bottom package of the stack is significantly reduced due to thermal resistance from various junctions and packages of the stack.

### SUMMARY

Various features relate to integrated circuit devices.

One example provides an integrated device that includes a first die, a second die stacked above the first die and electrically interconnected to the first die, and a conductive structure in thermal contact with a top surface of the first die and in thermal contact with a top surface of the second die. The conductive structure is configured to dissipate heat from the first die and the second die.

Another example provides a method of fabricating a package-on-package (PoP) device that includes attaching a first portion of a conductive structure to a top surface of a first die. The method also includes positioning a second die above the first die. The method further includes attaching a second portion of the conductive structure to a top surface of the second die.

Another example provides a device that includes an integrated device. The integrated device includes a first die, a second die stacked above the first die and electrically interconnected to the first die, and a first structure in thermal contact with a top surface of the first die and in thermal contact with a top surface of the second die. The first structure is configured to dissipate heat from the first die and the second die. The device also includes a printed circuit board (PCB) coupled to a bottom surface of the integrated device. The device further includes a second structure disposed above the integrated device and in thermal contact with the first structure. The second structure is configured to dissipate heat from the device.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1A illustrates a cross-sectional profile view of an exemplary integrated device that includes a structure for dissipating heat from stacked integrated circuit (IC) devices.

FIG. 1 illustrates a cross-sectional profile view of the exemplary integrated device of FIG. 1A.

FIG. 1C illustrates a cross-sectional top view of the exemplary integrated device of FIG. 1A.

FIG. 2 illustrates a cross-sectional profile view of a particular implementation of a device that includes the exemplary integrated device of FIG. 1A.

FIG. 3A illustrates a first part of an exemplary sequence for fabricating an exemplary integrated device that includes a structure for dissipating heat from stacked IC devices.

FIG. 3B illustrates a second part of an exemplary sequence for fabricating an exemplary integrated device that includes a structure for dissipating heat from stacked IC devices.

FIG. 3C illustrates a third part of an exemplary sequence for fabricating an exemplary integrated device that includes a structure for dissipating heat from stacked IC devices.

FIG. 4 illustrates an exemplary flow diagram of a method of fabricating an integrated device that includes a structure for dissipating heat from stacked IC devices.

FIG. 5 illustrates various electronic devices that may integrate an exemplary integrated device that includes a structure for dissipating heat from stacked IC devices described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure. As another example, various devices and structures disclosed herein are illustrated schematically. Such schematic representations are not to scale and are generally intentionally simplified. To illustrate, integrated devices can have many tens or hundreds of contacts and corresponding interconnections; however, a very small number of such contacts and interconnects are illustrated herein to highlight important features of the disclosure without unduly complicating the drawings.

Particular aspects of the present disclosure are described below with reference to the drawings. In the description, common features are designated by common reference numbers. As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and are subsequently referred to in the singular or optional plural (as indicated by “(s)”) unless aspects related to multiple of the features are being described.

As used herein, the terms “comprise,” “comprises,” and “comprising” may be used interchangeably with “include,” “includes,” or “including.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

Improvements in manufacturing technology and demand for lower cost and more capable electronic devices has led to increasing complexity of ICs. Often, more complex ICs have more complex interconnection schemes to enable interaction between ICs of a device. The number of interconnect levels for circuitry has substantially increased due to the large number of devices that are now interconnected in a state-of-the-art mobile application device.

These interconnections include back-end-of-line (BEOL) interconnect layers, which may refer to the conductive interconnect layers for electrically coupling to front-end-of-line (FEOL) active devices of an IC. The various BEOL interconnect layers are formed at corresponding BEOL interconnect levels, in which lower BEOL interconnect levels generally use thinner metal layers relative to upper BEOL interconnect levels. The BEOL interconnect layers may electrically couple to middle-of-line (MOL) interconnect layers, which interconnect to the FEOL active devices of an IC.

State-of-the-art mobile application devices demand a small form factor, low cost, a tight power budget, and high electrical performance. Mobile package design has evolved to meet these divergent goals for enabling mobile applications that support multimedia enhancements. For example, fan-out (FO) wafer level packaging (WLP) or FO-WLP process technology is a development in packaging technology that is useful for mobile applications. This chip first FO-WLP process technology solution provides flexibility to fan-in and fan-out connections from a die to package balls. In addition, this solution also provides a height reduction of a first level interconnect between the die and the package balls of mobile application devices. These mobile applications, however, are susceptible to power and signal routing issues when multiple dies are arranged within the small form factor.

Stacked die schemes and chiplet architectures are becoming more common as significant power performance area (PPA) yield enhancements are demonstrated for stacked die and chiplet architecture product lines. As used herein, “stacked dies” and/or “stacked ICs” refer to arrangements in which one die (e.g., a first die) is disposed over (including directly over) another die (e.g., a second die). Unfortunately, stacked die schemes can result in poor heat dissipation for at least some of the dies, resulting in significant heat accumulation and elevated temperatures at dies that are lower in the stack. Various aspects of the present disclosure provide a stacked IC device that includes a conductive structure configured to dissipate heat from the stacked IC device.

As used herein, the term “layer” includes a film, and is not construed as indicating a vertical or horizontal thickness unless otherwise stated. As used herein, the term “chiplet” may refer to an integrated circuit block, a functional circuit block, or other like circuit block specifically designed to work with one or more other chiplets to form a larger, more complex chiplet architecture.

Aspects of the present disclosure are directed to heat dissipation for stacked IC devices. In some aspects, an integrated device includes multiple stacked IC dies (e.g., multiple stacked IC devices) and a conductive structure configured to dissipate heat from the stacked IC dies. The conductive structure is in thermal contact with a top surface of a first die and in thermal contact with a top surface of a second die to provide heat transfer and dissipation to the first die along a thermal path that bypasses junctions between the first die and the second die, as well as intervening layers and the second die itself. The disclosed integrated device with the conductive structure provides improved heat dissipation and cooling for stacked IC devices, such as a system-on-chip (SoC) device stacked below a dynamic random-access memory (DRAM) without significantly increasing fabrication costs and complexity.

### Exemplary Integrated Device Including a Conductive Structure

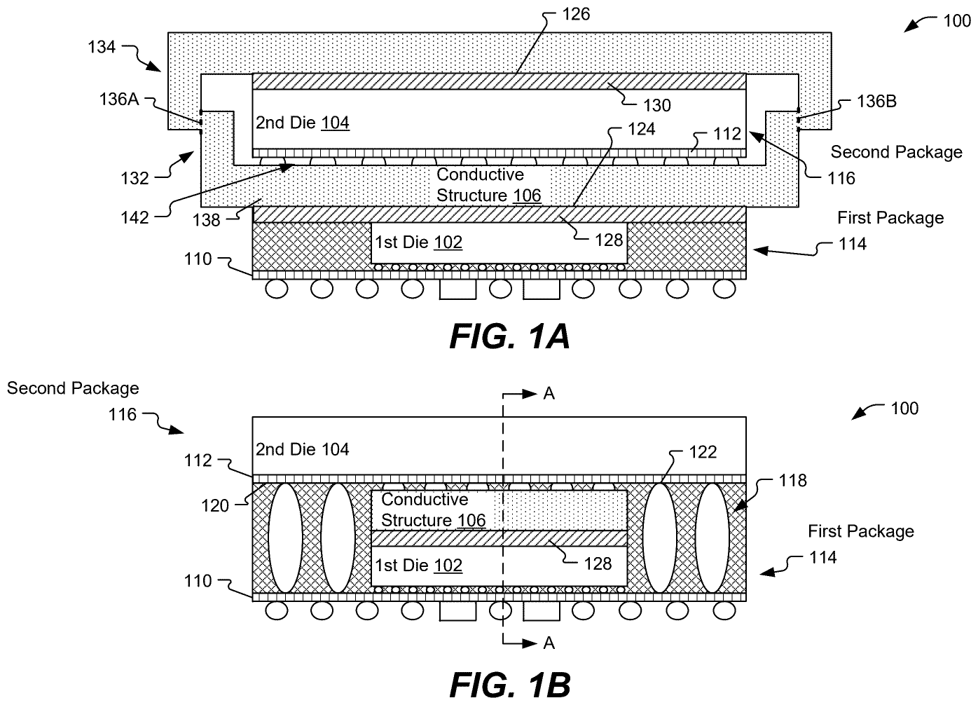

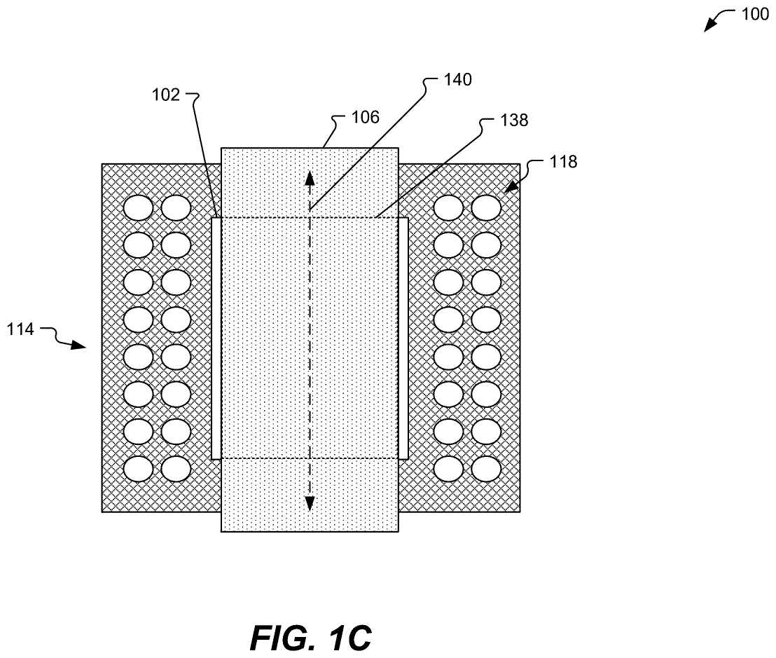

FIG. 1A illustrates a cross-sectional profile view of an exemplary integrated device 100 that includes a structure for dissipating heat from stacked integrated circuit (IC) devices. FIG. 1B illustrates a cross-sectional profile view of the exemplary integrated device 100 of FIG. 1A. The cross-sectional profile view illustrated in FIG. 1A is along the line A-A in FIG. 1B. FIG. 1C illustrates a cross-sectional top view of the exemplary integrated device 100 of FIG. 1A.

In the implementation shown in FIG. 1A, the integrated device 100 includes a plurality of dies, such as a first die 102 and a second die 104, and a conductive structure 106. Each of the dies 102, 104 can include integrated circuitry, such as a plurality of transistors and/or other circuit elements arranged and interconnected to form logic cells, memory cells, etc. Components of the integrated circuitry can be formed in and/or over a semiconductor substrate. Different implementations can use different types of transistors, such as a field effect transistor (FET), planar FET, finFET, a gate all around FET, or mixtures of transistor types. In some implementations, a front end-of-line (FEOL) process may be used to fabricate the integrated circuitry in and/or over the semiconductor substrate.

The plurality of dies included in the integrated device 100 are stacked and electrically interconnected to form stacked IC devices. In the example shown in FIGS. 1A and 1B, the second die 104 is stacked above the first die 102 and electrically interconnected to the first die 102. Stated another way, the second die 104 may be disposed over the first die 102 in the integrated device 100. The first die 102 and the second die 104 may include or correspond to particular IC devices that can be arranged and interconnected as a three-dimensional (3D) IC device. In some implementations, the first die 102 includes or corresponds to an application processor and the second die 104 includes or corresponds to a dynamic random-access memory (DRAM). The application processor may be part of a system-on-chip (SoC) that is implemented by the first die 102. Additionally, or alternatively, the first die 102 may include one or more microcontrollers, application specific integrated circuits (ASICs), field programmable gate arrays (FPGAs), central processing units (CPUs) having one or more processing cores, processing systems, or other circuitry and logic configured to facilitate the operations of the SoC. Additionally, or alternatively, the DRAM (e.g., the second die 104) may be compliant with one or more industry standards, such as a Joint Electron Tube Engineering Council (JEDEC®) standard (JEDEC is a registered trademark of the JEDEC Solid State Technology Association). Although described as a DRAM, in other implementations, the second die 104 may include or correspond to a different type of memory, such as a static random-access memory (SRAM), flash memory, read-only memory (ROM), programmable read-only memory (PROM), erasable programmable read-only memory (EPROM), electrically erasable programmable read-only memory (EEPROM), a solid-state storage device (SSD), or a combination thereof.

In some implementations, the IC dies are electrically connected to, or integrated with, respective substrates. For example, the first die 102 may be electrically connected (e.g., via one or more contacts) to a first substrate 110 and the second die 104 may be electrically connected to a second substrate 112. In some implementations, the pairs of dies and substrates may be parts of stacked packages. For example, the first die 102 may be included within a first package 114 on (or that includes) the first substrate 110 and the second die 104 may be included within a second package 116 on (or that includes) the second substrate 112. In some implementations, the first package 114 and the second package 116 are arranged in a package-on-package (POP) configuration. For example, the second package 116 may be disposed above (e.g., over) the first package 114.

In some implementations, the first substrate 110 and the second substrate 112 have signal propagation paths formed between each other. As shown in FIG. 1B, the integrated device 100 includes electrical interconnects 118 that form signal propagation paths between the first substrate 110 and the second substrate 112. The electrical interconnects 118 may be connected or coupled to contacts on each of the substrates 110, 112 to form the signal propagation paths between the substrates 110, 112. For example, a bottom surface 120 (e.g., in the orientations shown in FIGS. 1A and 1B) of the second substrate 112 have a plurality of electrical contacts, such as an illustrative contact 122, that may be electrically coupled to a plurality of contacts (not shown) on a top surface (e.g., in the orientations shown in FIGS. 1A and 1B) of the first substrate 110 to enable propagation of signals between the substrates 110, 112. In some implementations, an arrangement of the electrical contacts, including the illustrative contact 122, on the bottom surface 120 of the second substrate 112 matches an arrangement of the electrical interconnects 118, such that there exist signal propagation paths from the contacts of the second substrate 112 to the first substrate 110 via the electrical interconnects 118. The electrical interconnects 118 may be any type of structure or feature that supports signal propagation through integrated circuit packages. For example, the electrical interconnects 118 may include interposer-POP (IOP) balls or other IOP contacts. Alternatively, the electrical interconnects 118 may include through-mold vias (TMVs).

In some implementations, the electrical contacts, including the illustrative contact 122, on the bottom surface 120 of the second substrate 112 and the electrical interconnects 118 are arranged such that the electrical contacts and the electrical interconnects 118 are not disposed within a region in which the first die 102 and the conductive structure 106 are disposed, as further described herein. Such arrangement of the electrical contacts and the electrical interconnects 118, as well as electrical contacts on the top surface of the first substrate 110, may enable formation of the signal propagation paths between the substrates 110, 112 in a manner that reduces a height of the integrated device 100. To illustrate, the electrical interconnects 118 may extend from the first substrate 110 to the electrical contacts on the bottom surface 120 of the second substrate 112 to form the signal propagation paths without an intervening interposer substrate between the first substrate 110 and the second substrate 112, such as an interposer substrate that provides signal propagation paths between different arrangements of electrical contacts on opposing substrates. Omitting such an interposer substrate results in the integrated device 100 having reduced height as compared to other stacked devices that include one or more interposers between circuit dies.

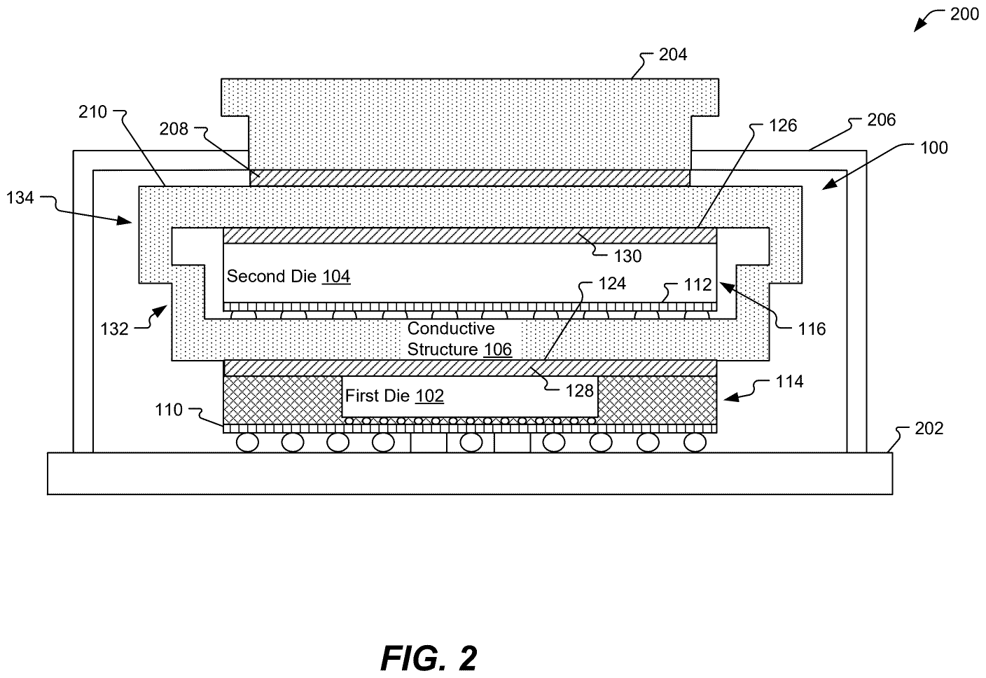

The integrated device 100 also includes the conductive structure 106 that is configured to dissipate heat from the first die 102 and the second die 104. In the example shown in FIG. 1A, the conductive structure 106 is in thermal contact with a top surface 124 of the first die 102 and in thermal contact with a top surface 126 of the second die 104. The conductive structure 106 is configured to dissipate heat from the first die 102 and the second die 104 by providing thermal pathways to a top portion of the conductive structure 106, which may be open or connected to another cooling device, as further described herein with reference to FIG. 2, or to spread heat along the thermal pathways of the conductive structure 106 to move heat from adjacent to a hotter IC device to areas adjacent to lower temperature components and/or to more evenly spread heat throughout the conductive structure 106, thereby cooling or dissipating heat from the hottest components of the integrated device 100. The conductive structure 106 may include a thermally conductive foil that is capable of conducting heat from regions associated with higher temperatures to regions associated with lower temperatures. For example, the thermally conductive foil may include copper, aluminum, a copper alloy, an aluminum alloy, another metal or metal alloy, or a combination thereof.

In some implementations, the conductive structure 106 is in direct contact with the top surface 124 of the first die 102, the top surface 126 of the second die 104, or both. Alternatively, the conductive structure 106 may be in thermal contact with the top surface 124, the top surface 126, or both, via one or more intervening layers or materials. In some examples, the conductive structure 106 is in thermal contact with the top surface 124 of the first die 102 via a first thermal interface material 128. Additionally, or alternatively, the conductive structure 106 may be in thermal contact with the top surface 126 of the second die 104 via a second thermal interface material 130. To illustrate, the first thermal interface material 128 may be disposed on a surface of the first die 102 and at least a portion of a mold compound used to form the first package 114, and the second thermal interface material 130 may be disposed on a surface of the second die 104 (and optionally some of the mold compound of the second package 116). The first thermal interface material 128, the second thermal interface material 130, or both, may be any material capable of providing a thermally conductive interface between the conductive structure 106 and the respective die, such as thermal adhesives, gap filler pads, phase change materials, electrical insulation materials, other materials, or a combination thereof. In some implementations, the first thermal interface material 128 and the second thermal interface material 130 are the same material. In other implementations, the first thermal interface material 128 and the second thermal interface material 130 are different materials.

To provide the above-described thermal pathways, the conductive structure 106 may at least partially encircle the second die 104 (e.g., the second package 116). For example, the conductive structure 106 may have a ring shape that at least partially encircles the second die 104, as shown in FIG. 1A. Although described as a ring shape, the shape of the conductive structure 106 may substantially be another shape that encircles or at least partially surrounds the second die 104. For example, the shape of the conductive structure 106 may be circular, elliptical, rectangular, square, polygonal, or the like, and may be formed having curved portions, straight portions connected to each other at various angles, or a combination thereof.

In some implementations, the conductive structure 106 may be formed from multiple pieces to reduce the complexity of a fabrication process. In some examples, the conductive structure 106 includes two pieces, each corresponding to one of the dies 102, 104. For example, the conductive structure 106 may include a first piece 132 attached to the top surface 124 of the first die 102 and a second piece 134 attached to the top surface 126 of the second die 104 and to the first piece 132. In this example, each of the pieces 132, 134 may be approximately semi-circular, such that when combined, the pieces 132, 134 form the ring shape of the conductive structure 106 that at least partially encircles the second die 104 (e.g., the second package 116). Although described as semi-circular, the pieces 132, 134 may be curved or may be formed from straight portions connected at angles (e.g., two substantially U-shaped pieces). In some examples, the first piece 132 is attached to the second piece 134 via one or more mechanical detents 136. To illustrate, a first end of the first piece 132 may be attached to a first end of the second piece 134 via a mechanical detent 136A and a second end of the first piece 132 may be attached to a second end of the second piece 134 via a mechanical detent 136B.

In some implementations, the mechanical detents 136 may include a catch, a bump, or an extended edge of one of the pieces 132, 134 that is configured to be caught in an opening, recess, cavity, or latch on the other of the pieces 132, 134. As a non-limiting example, if the second piece 134 is a substantially semicircular or U-shaped piece that is larger than the first piece 132, which is also substantially semicircular or U-shaped, as shown in FIG. 1A, the mechanical detent 136A may include an opening or latch on an edge of the second piece 134 that faces an edge of the first piece 132 which includes a catch or a bump so that, when the pieces 132, 134 are snapped together, causes the pieces 132, 134 to remain interlocked (e.g., in contact with each other) as the singular conductive structure 106. In other implementations, other types of mechanical detents 136 or connecting mechanisms or structures may be used. The pieces 132, 134 may be snapped together such that the pieces 132, 134 are held together as a single combined piece by the mechanical detents 136. Forming the conductive structure 106 from multiple distinct pieces that can be attached to the dies 102, 104 during fabrication may result in a higher volume fabrication process as compared to using a conductive structure formed from a single piece.

In some other implementations, the conductive structure 106 may have a different shape than a ring shape, the conductive structure 106 may include more than two pieces or a single piece, or both. As a non-limiting example, the conductive structure 106 may have a substantially C-shape that partially encircles the second die 104. To illustrate, the conductive structure 106 may be formed of a single piece that omits the adjacent straight edges (e.g., conductive elements or portions) of the first piece 132 and the second piece 134 on either the left side (e.g., near the mechanical detent 136A) or the right side (e.g., near the mechanical detent 136B) of FIG. 1A. As an example, the conductive structure 106 may include a conductive element between the first die 102 and the second die 104, a conductive element above the second die 104, and a conductive element connecting the other two conductive elements along one side of the second die 104 to form a single conductive structure. Such implementations of the conductive structure 106 may be formed by bending a copper foil to obtain a substantially C-shape. The shape may be curved or formed having straight edges bent at substantially right angles. In other implementations, the conductive structure 106 has other shapes.

The conductive structure 106 may be disposed within the integrated device 100 such that the conductive structure 106 does not overlap any of the electrical interconnects 118. To illustrate, the conductive structure 106 may include a conductive element 138 that extends along a pathway 140 that is devoid of the electrical interconnects 118 between the first substrate 110 and the second substrate 112, as shown in FIG. 1C. As shown in FIGS. 1B and 1C, the electrical interconnects 118 may be arranged in locations that are not occupied by the first die 102 and the conductive structure 106. It is noted that FIG. 1B omits the second piece 134, the side portions of the first piece 132 shown in FIG. 1A, and the second thermal interface material 130 for clarity of illustration. It is also noted that FIG. 1C omits components above the conductive element 138 (e.g., the second piece 134, the second die 104, and others) for clarity of illustration.

In some implementations, the integrated device 100 includes an optional underfill layer 142 that is disposed between the bottom surface 120 of the second die 104 (e.g., a bottom surface of the second substrate 112) and the conductive structure 106. For example, the underfill layer 142 may be disposed between a top surface of the conductive element 138 and the bottom surface 120 of the second substrate 112, such that the underfill layer 142 fills in between one or more electrical contacts on the bottom surface 120 of the second die 104 that are not arranged to be connected to the electrical interconnects 118. The underfill layer 142 may include dielectric materials, polymers, adhesives, other underfill materials, or a combination thereof. In other implementations, the underfill layer 142 may be an air gap layer. In other implementations, the underfill layer 142 may be omitted.

It should be understood that the integrated device 100 may include additional components, other components, fewer components, or a combination thereof, to support the functionality described herein. As non-limiting examples, the integrated device 100 may include additional IC devices, additional layers, additional dies, additional packages, additional interconnects, additional structures, other components, different components, or a combination thereof, to support the functionality and technical advantages disclosed herein.

During operation of the integrated device 100, the integrated device 100 operates as part of a molded embedded package (MEP) POP device or molded laser package (MLP) with the conductive structure 106 operating as an embedded heat dissipation or spreader ring for the integrated device 100. Unlike other heat dissipation structures which are thermally connected to the top of a stacked IC device and provide a thermal pathway for heat dissipation through the intervening dies and layers, the conductive structure 106 provides effective heat dissipation and removal from the first die 102 through the conductive element 138 that that extends along the pathway 140 between the first substrate 110 and the second substrate 112. Heat dissipation is improved because the conductive structure 106 provides multiple thermal pathways (e.g., toward either side of the conductive element 138 and around the second die 104 and the second substrate 112) that conduct heat in parallel and that each have lower overall thermal resistance than a thermal pathway from the first die 102 through the second die 104 and intervening layers to a top of the conductive structure 106.

The integrated device 100 thus experiences improved heat dissipation from the conductive structure 106 as compared to other heat dissipation devices that coupled to the top of stacked IC devices. For example, the conductive structure 106 may be in thermal contact with top surfaces of both the first die 102 and the second die 104. A technical advantage of the conductive structure 106 includes enabling improved heat dissipation via thermal pathways that bypass junctions between the first die 102 and the second die 104, as well as intervening layers and the second die 104 itself, such that thermal resistance along the thermal pathways from the first die 102 to the top of the integrated device 100 (e.g., to the top of the conductive structure 106) is reduced as compared to the other types of heat dissipation or cooling devices. The improved heat dissipation reduces temperature at the first die 102 through conduction of heat away from the first die via the parallel thermal pathways having reduced thermal resistance.

Additionally, because the heat does not travel through the second die 104, the temperature of the second die 104 is reduced as compared to cooling provided by other heat dissipation devices. As such, the integrated device 100 including an SoC device (e.g., the first die 102) can be operated at higher performance levels for extended durations while keeping a DRAM (e.g., the second die 104) cooler than with other heat dissipation devices configured for use with stacked IC devices. As a non-limiting example, in an implementation that does not include the underfill layer 142, a conductive structure 106 formed from copper and having a thickness of 100 micrometers (μm) may reduce SoC die max temperature by 14% and DRAM max temperature by 16% as compared to other heat dissipation devices, and an implementation that includes the underfill layer 142 may reduce SoC die max temperature by 20% and DRAM max temperature by 9%. The improved heat dissipation can be achieved with minimal impact on device form factor (e.g., the conductive structure 106 does not substantially increase the height of the integrated device 100, and the increased height can be mitigated by arranging the electrical interconnects 118 such that an interposer substrate is not included between the first substrate 110 and the second substrate 112) and without impacting overall electrical performance of the integrated device 100.

FIG. 2 illustrates a cross-sectional profile view of a particular implementation of a device 200 that includes the exemplary integrated device 100 of FIG. 1A. The device 200 of FIG. 2A includes many of the same components and features as are described above with reference to FIGS. 1A-C. Such components and features are physically and operationally the same as described above with reference to FIGS. 1A-C and are labeled in FIG. 2 using the same reference numbers. In some implementations, the device 200 includes all of the same features and components as the integrated device 100 of FIGS. 1A-C; however, some components and features illustrated in FIGS. 1A-C have been omitted from (or are not labeled with reference numbers in) FIG. 2 for simplicity of illustration and to highlight differences between the integrated device 100 and the device 200. Omission of such features and reference numbers should not be understood as limiting the features and components of FIG. 2 to only those specifically called out below. For example, while FIG. 2 does not show the electrical interconnects 118 of FIG. 1B or the optional underfill layer 142, the device 200 can include the electrical interconnects 118 (e.g., in a different view) and/or the optional underfill layer 142.

In the example shown in FIG. 2, the device 200 includes the integrated device 100 and a printed circuit board (PCB) 202. In some examples, the PCB 202 is coupled to a bottom surface of the integrated device 100 (e.g., a bottom surface of the first substrate 110 via one or more contacts). The device 200 also includes a second structure 204 that is disposed above the integrated device 100 and is in thermal contact with the conductive structure 106. The second structure 204 may include a heat sink, a vapor chamber, a conductive device (e.g., copper, or another metal or metal alloy), or another type of heat dissipating or spreading device, another type of cooling device, or a combination thereof. In some implementations, the device 200 includes an optional housing 206 (e.g., an external housing) configured to support the second structure 204 and attach the second structure 204 to the PCB 202.

In some aspects, the second structure 204 is configured to dissipate heat from the integrated device 100, from other components of the device 200, or a combination thereof. To provide heat dissipation and cooling to the integrated device 100, the second structure 204 may be in thermal contact with a top surface of the integrated device 100 (e.g., the conductive structure 106). In some implementations, the second structure 204 is in direct contact with a top surface 210 of the conductive structure 106. Alternatively, the second structure 204 may be in thermal contact with the top surface 210 via one or more intervening layers or materials, such as a third thermal interface material 208. The third thermal interface material 208 may be the same material or different material as the first thermal interface material 128 and the second thermal interface material 130. Because of the thermal contact between the second structure 204 and the conductive structure 106, the conductive structure 106 provides a thermal pathway from the first die 102 to the second structure 204 and a thermal pathway from the second die 104 to the second structure 204.

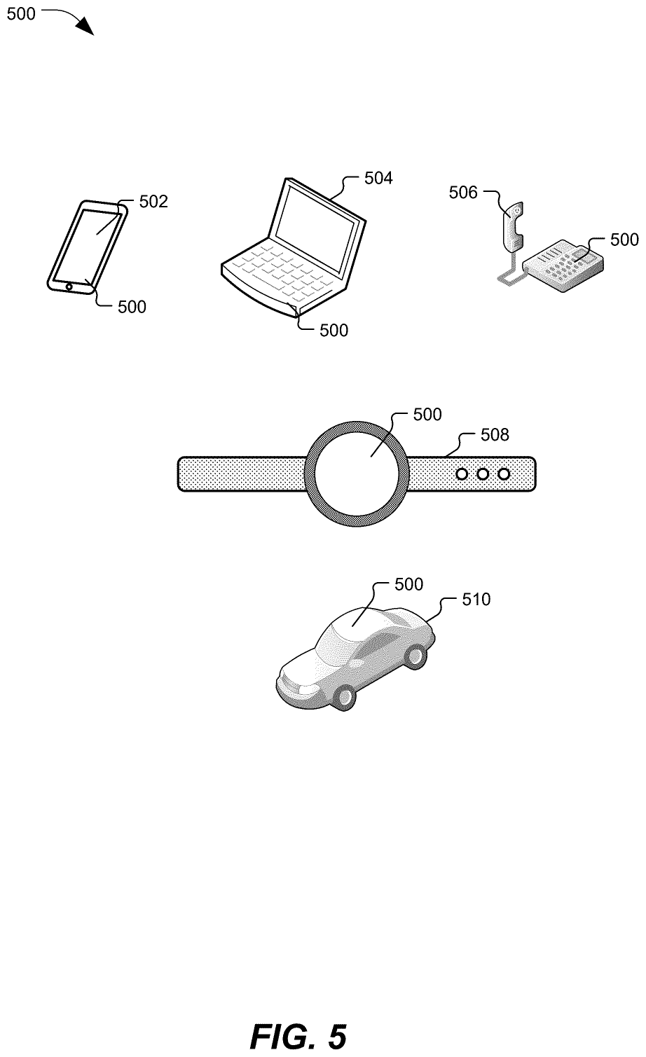

In some implementations, the device 200 can be integrated in a smartphone, a tablet computer, a fixed location terminal device, an automobile, a wearable electronic device, a laptop computer, or some combination thereof, as described in more detail below with reference to FIG. 5. As described with reference to FIG. 2, the device 200 includes the integrated device 100 and the second structure 204 to provide extra cooling and heat dissipation for the device 200. A technical advantage of locating the second structure 204 in thermal contact with the conductive structure 106 is to reduce operating temperatures of the first die 102 (e.g., an SoC) and the second die 104 (e.g., a DRAM). For example, providing multiple thermal pathways from the first die 102 to the second structure 204 (e.g., via the ring shape of the conductive structure 106) that have reduced thermal resistance can reduce the temperature of the first die 102, and dissipating heat from the first die 102 around, instead of through, the second die 104 can reduce the temperature of the second die 104, as compared to other heat dissipation devices.

While FIG. 2 illustrates an example device that includes two packages stacked to form an integrated device, in other examples, one or more additional integrated devices, packages, or some combination thereof can be present in a stacked integrated circuit without departing from the scope of the subject disclosure. Further, while FIG. 2 illustrates an integrated device in the context of a memory package, the integrated device disclosed herein can be integrated with or included within a wide variety of other devices. For example, a device that includes one or more of the integrated devices disclosed herein can include components such as a power management integrated circuit (PMIC), an application processor, a modem, a radio frequency (RF) device, a passive device, a filter, a capacitor, an inductor, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. In such devices, the integrated device can operate as any of these components (or a combination of these components) that includes active circuitry.

### Exemplary Sequence for Fabricating an Integrated Device Including a Conductive Structure

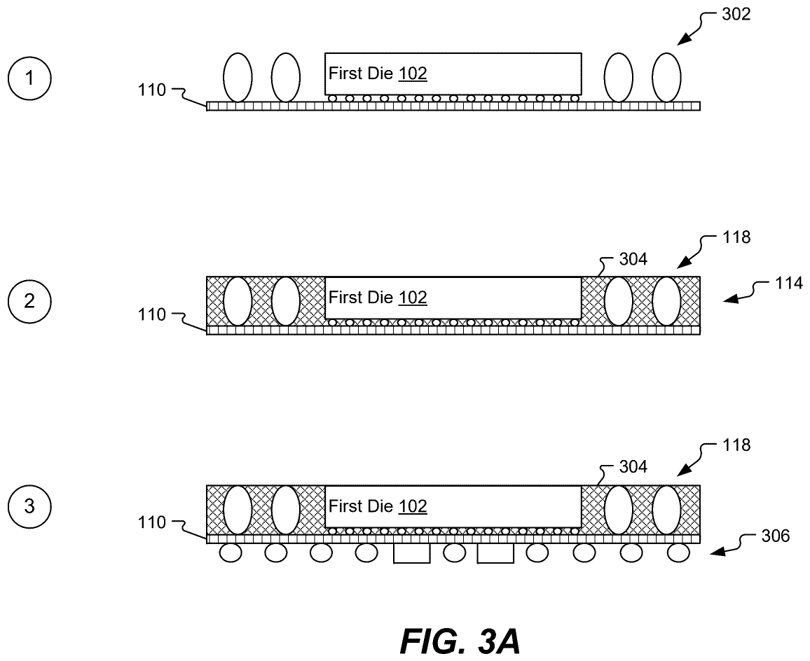

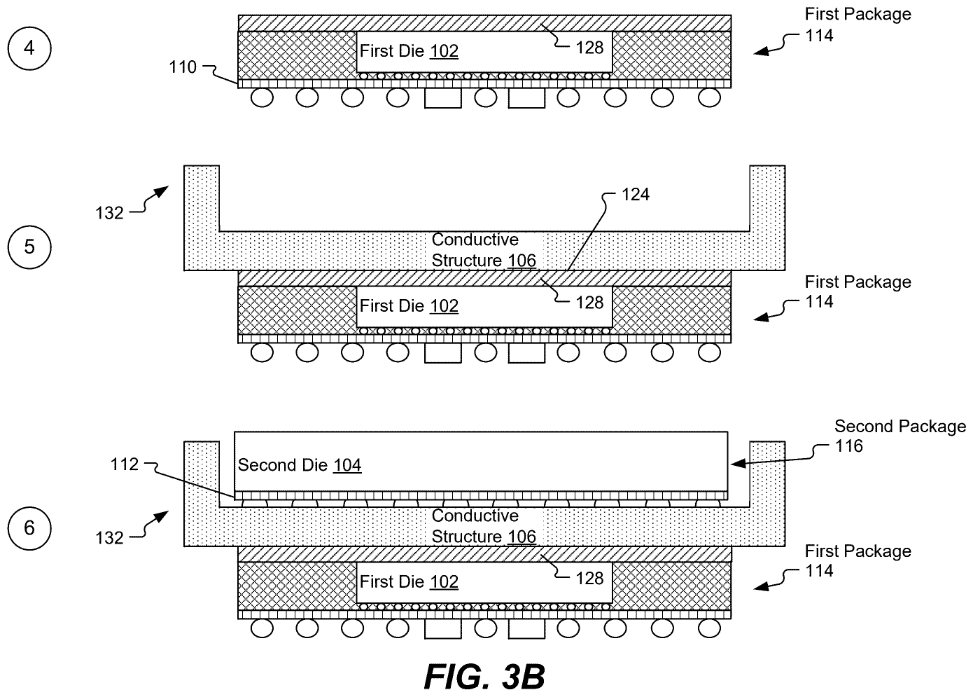

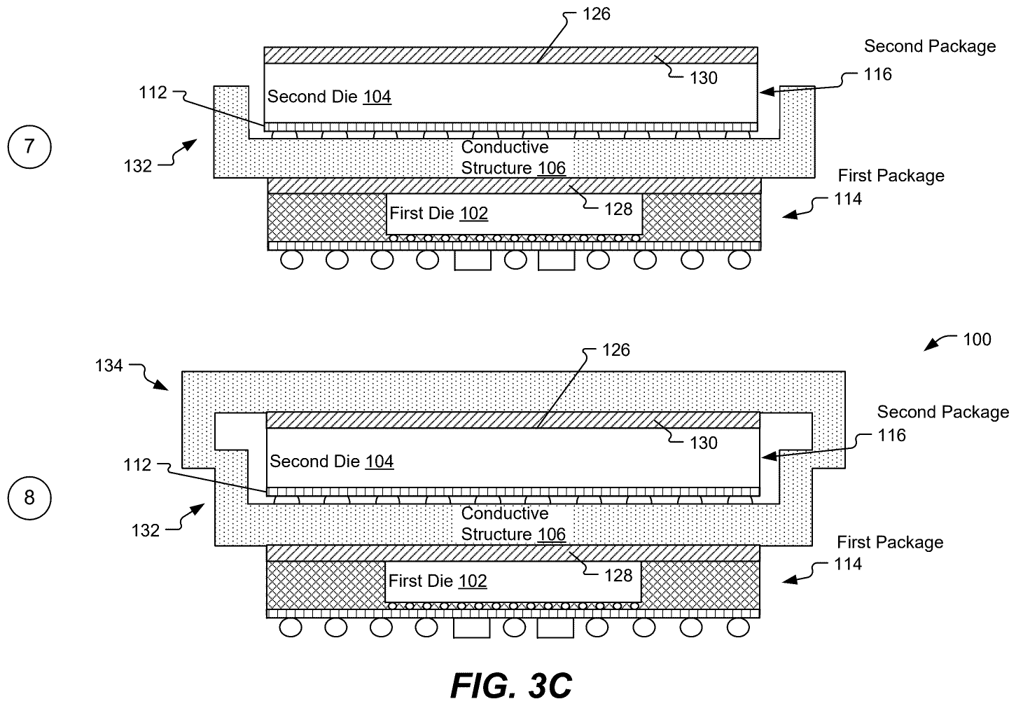

In some implementations, fabricating the integrated device 100 includes several processes. FIGS. 3A-C illustrate an exemplary sequence for fabricating an integrated device that includes a structure for dissipating heat from stacked IC devices, as described with reference to any of FIGS. 1A-C and 2. In some implementations, the sequence of FIGS. 3A-C may be used to provide (e.g., during fabrication of) one or more of the integrated device 100 of FIGS. 1A-C or the device 200 of FIG. 2.

It should be noted that the sequence of FIGS. 3A-C may combine one or more stages in order to simplify and/or clarify the sequence for providing or fabricating an integrated device. In some implementations, the order of the processes may be changed or modified. In some implementations, one or more of the processes may be replaced or substituted without departing from the scope of the disclosure. In the following description, reference is made to various illustrative Stages of the sequence, which are numbered (using circled numbers) in FIGS. 3A-C. Each of the various stages of the sequence illustrated in FIGS. 3A-C shows a single integrated device being formed. In other implementations, a plurality of integrated devices can be formed concurrently.

Stage 1 of FIG. 3A illustrates a state after the first die 102 (e.g., an SoC die) and the first substrate 110 have been coupled to one another. For example, as part of Stage 1, a set of electrical contacts of the first die 102 can be electrically coupled to a subset of contacts of the first substrate 110. In some implementations, Stage 1 also illustrates the state after a first set of bumps 302 (e.g., contact bumps) have been coupled to the first substrate 110. The first set of bumps 302 may include or correspond to controlled collapsed bonding (CCB) bumps or balls, solder balls, or another type of material used to form metal interconnects in semiconductor devices. In other implementations, the first set of bumps 302 may be omitted, and electrical interconnects may be formed using vias, as further described below.

Stage 2 illustrates a state after over molding is performed on the first die 102 and the first substrate 110 to form the first package 114 and after mold grinding is performed to expose the SoC (e.g., the first die 102). To illustrate, as part of Stage 2, packaging material may be deposited or otherwise disposed on the first die 102 and the first substrate 110 to form the first package 114. Such deposition (or other technique) may result in the packaging material covering the first die 102 and the first substrate 110. Accordingly, as part of Stage 2, a top surface 304 of the first package 114 may be grinded (e.g., via a mold grinding process) to expose a top surface of the first die 102.

In some implementations in which the first set of bumps 302 are included, the packaging material is also deposited over the first set of bumps 302, and Stage 2 illustrates the state after grinding is performed to expose top surfaces of the first set of bumps 302. Exposing the first set of bumps 302 may enable the first set of bumps 302 to form the electrical interconnects 118 (e.g., once the second substrate 112 is added). Alternatively, in some implementations in which the first set of bumps 302 are omitted, Stage 2 includes patterning or otherwise forming a set of TMVs in the locations of the first set of bumps 302 in FIG. 3A to operate as the electrical interconnects 118.

Stage 3 illustrates a state after ball grid array (BGA) contacts 306 and/or other contacts are coupled to a bottom of the first substrate 110. For example, the BGA contacts 306 may include one or more contacts of a BGA for coupling to a PCB (e.g., the PCB 202 of FIG. 2). Stage 3 may also illustrate the state after singulation and a bottom test are performed as part of a semiconductor fabrication process.

Stage 4 of FIG. 3B illustrates a state after the first thermal interface material 128 is formed on the first die 102 (e.g., on the exposed surface of the SoC device) and a surface of the first package 114 (e.g., a surface of the mold compound used to form the first package 114. For example, a layer of a thermal interface material may be deposited on the exposed surface of the first die 102 (e.g., after the grinding) to form the first thermal interface material 128. It is noted that, in FIG. 3B, the first substrate 110 and the first die 102 have been rotated approximately 90 degrees as compared to the views shown in FIG. 3A.

Stage 5 illustrates a state after the first piece 132 (e.g., a first portion) of the conductive structure 106 is attached to the first die 102. For example, a bottom surface of the first piece 132 of the conductive structure 106 may be coupled to the top surface 124 of the first die 102. Coupling the first piece 132 to the top surface 124 places the conductive structure 106 in thermal contact with the first die 102. In some implementations, the first piece 132 is attached to the top surface 124 via the first thermal interface material 128. In some other implementations, the first thermal interface material 128 and Stage 4 are omitted, and the first piece 132 is directly attached to the top surface 124.

Stage 6 illustrates a state after the second die 104 (e.g., a DRAM) is positioned above the first die 102 and coupled to the first piece 132 of the conductive structure 106. For example, the second die 104 may be part of the second package 116 that is formed on the second substrate 112, and a first subset of contacts on the bottom of the second substrate 112 may be coupled to the first piece 132. In some implementations, some of the operations of Stages 1-3 may be performed to also form the second package 116 for placement upon the first piece 132. Alternatively, the second package 116 (e.g., including the second substrate 112 and the second die 104) may be separately fabricated or formed according to another process.

Stage 7 of FIG. 3C illustrates a state after the second thermal interface material 130 is formed on the second die 104 (e.g., on the DRAM). For example, a layer of a thermal interface material may be deposited on the top surface 126 of the second die 104 (e.g., the second package 116) to form the second thermal interface material 130. The second thermal interface material 130 may be the same material or a different material than the first thermal interface material 128.

Stage 8 illustrates a state after the second piece 134 of the conductive structure 106 is attached to the second die 104. For example, the second piece 134 may be attached or coupled to the first piece 132 and to the top surface 126 of the second die 104. Coupling the second piece 134 to the top surface 126 places the conductive structure 106 in thermal contact with the second die 104. In some implementations, the second piece 134 is attached to the top surface 126 via the second thermal interface material 130. In some other implementations, the second thermal interface material 130 and Stage 7 are omitted, and the second piece 134 is directly attached to the top surface 126.

In some implementations, the first piece 132 and the second piece 134 include features that enable the second piece 134 to snap together (e.g., to become interlocked) with the first piece 132. For example, the second piece 134 may be snapped to the first piece 132 at one or more mechanical detents, such as the mechanical detents 136 described above with reference to FIG. 1A. Attaching the second piece 134 to the first piece 132 forms the conductive structure 106 (e.g., as a unitary structure having a ring shape). Formation of the integrated device 100 (e.g., an integrated IC device including stacked IC devices and a conductive structure for dissipating heat from the stacked IC devices) is complete after stage 8 of FIG. 3C.

Although certain Stages are illustrated in FIGS. 3A-C in forming the integrated device 100, other processes can be included in the fabrication of the integrated device 100 without departing from the scope of the subject disclosure. For example, fabricating the integrated device 100 can include adding the underfill layer 142 between the second substrate 112 and the conductive structure 106. This can include adding the underfill material prior to or after coupling the second die 104 to the conductive structure 106. Additionally, or alternatively, the integrated device 100 can be used to form the device 200 of FIG. 2. For example, the integrated device 100 (e.g., a bottom surface of the first substrate 110) may be coupled to a PCB (e.g., the PCB 202 of FIG. 2). Additionally, or alternatively, a second structure (e.g., the second structure 204 of FIG. 2) may be placed in thermal contact with a top surface (e.g., the top surface 210 of FIG. 2) of the conductive structure 106, either directly or via the third thermal interface material 208.

### Exemplary Flow Diagram of a Method for Fabricating an Integrated Device Including a Conductive Structure

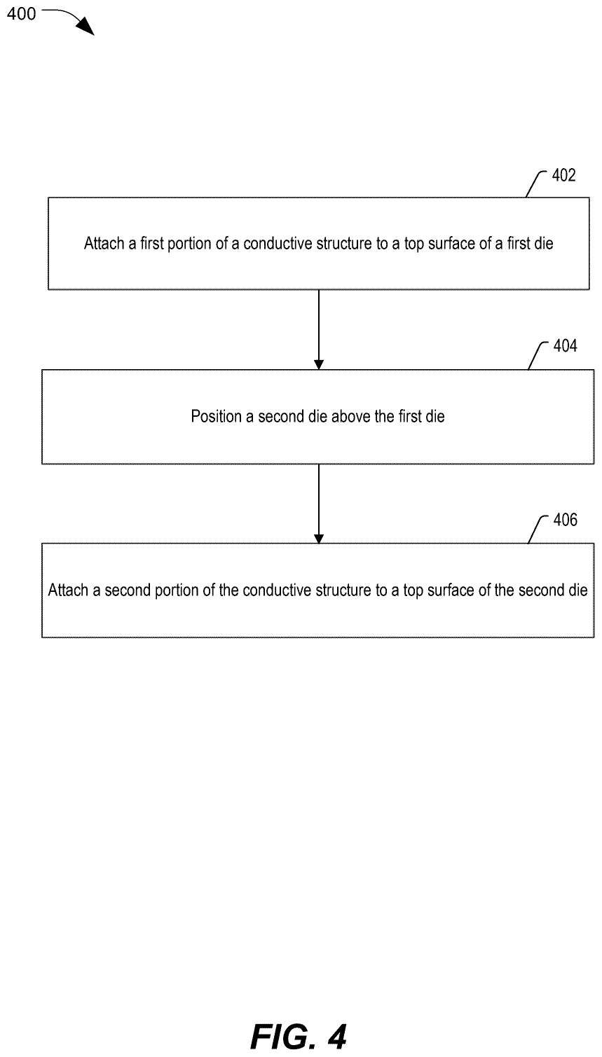

In some implementations, fabricating an IC device includes several processes. FIG. 4 illustrates an exemplary flow diagram of a method 400 of fabricating an illustrative integrated device that includes a structure for dissipating heat from stacked IC devices. In a particular aspect, one or more operations of the method 400 are performed by one or more processors of a fabrication system. In some implementations, operations of the method 400 may be stored as instructions by a non-transitory computer-readable storage medium, and the instructions may be executable by at least one processor to cause the at least one processor to perform operations of the method 400. In some implementations, the method 400 of FIG. 4 may be used to provide or fabricate any of the integrated device 100 or the device 200 of FIGS. 1A-3C.

It should be noted that the method 400 of FIG. 4 may combine one or more processes in order to simplify and/or clarify the method for providing or fabricating an integrated circuit device. In some implementations, the order of the processes may be changed or modified.

The method 400 includes attaching a first portion of a conductive structure to a top surface of a first die, at block 402. For example, Stage 5 of FIG. 3B illustrates and describes examples of coupling the first piece 132 of the conductive structure 106 to the first die 102. The first die of the method 400 can include the first die 102 of FIGS. 1A-3C. The conductive structure of the method 400 can include the conductive structure of FIGS. 1A-3C. The first portion of the conductive structure of the method 400 can include the first piece 132 of FIGS. 1A-3C. In some implementations, the first portion is attached to the top surface of the first die via a thermal interface material. Stage 4 of FIG. 3B illustrates and describes examples of attaching the first thermal interface material 128 to the first die 102, and Stage 5 of FIG. 3B illustrates and describes examples of coupling the conductive structure 106 to the first thermal interface material 128. The thermal interface material of the method 400 can include the first thermal interface material 128 of FIGS. 1A-3C.

The method 400 also includes positioning a second die above the first die, at block 404. For example, Stage 6 of FIG. 3B illustrates and describes examples of positioning the second die 104 above the first die 102. The second die of the method 400 can include the second die 104 of FIGS. 1A-3C.

The method 400 further includes attaching a second portion of the conductive structure to a top surface of the second die, at block 406. For example, Stage 8 of FIG. 3C illustrates and describes examples of attaching the second piece 134 of the conductive structure 106 to the top surface 126 of the second die 104. The second portion of the conductive structure of the method 400 can include the second piece 134 of FIGS. 1A-3C. In some implementations, the second portion is attached to the top surface of the second die via a thermal interface material. For example, Stage 7 of FIG. 3C illustrates and describes examples of attaching the second thermal interface material 130 to the top surface 126 of the second die 104, and Stage 8 of FIG. 3C illustrates and describes examples of attaching the conductive structure 106 to the top surface 126 via the second thermal interface material 130. The thermal interface material of the method 400 can include the second thermal interface material 130 of FIGS. 1A-3C.

In some implementations, the method 400 also includes snapping the first portion to the second portion at one or more mechanical detents to form the conductive structure. For example, Stage 8 of FIG. 3C illustrates and describes examples of snapping the first piece 132 to the second piece 134. The one or more mechanical detents of the method 400 can include the mechanical detents 136 of FIGS. 1A-3C.

### Exemplary Electronic Devices

FIG. 5 illustrates various electronic devices that may include or be integrated with any of the integrated device 100 (that includes the conductive structure 106) or the device 200. For example, a mobile phone device 502, a laptop computer device 504, a fixed location terminal device 506, a wearable device 508, or a vehicle 510 (e.g., an automobile or an aerial device) may include a device 500. The device 500 can include, for example, any of the integrated device 100 or the device 200, and/or any other integrated device that includes a conductive structure described herein. The devices 502, 504, 506 and 508 and the vehicle 510 illustrated in FIG. 5 are merely exemplary. Other electronic devices may also feature the device 500 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in vehicles (e.g., autonomous vehicles), or any other device that stores or retrieves data or computer instructions, or any combination thereof.

One or more of the components, processes, features, and/or functions illustrated in FIGS. 1A-5 may be rearranged and/or combined into a single component, process, feature or function or embodied in several components, processes, or functions. Additional elements, components, processes, and/or functions may also be added without departing from the disclosure. It should also be noted FIGS. 1A-5 and its corresponding description in the present disclosure is not limited to dies and/or ICs. In some implementations, FIGS. 1A-5 and its corresponding description may be used to manufacture, create, provide, and/or produce devices and/or integrated devices. In some implementations, a device may include a die, an integrated device, an embedded multi-chip package, an integrated passive device (IPD), a die package, an IC device, a device package, an IC package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first,” “second,” “third,” and “fourth” (and/or anything above fourth) is arbitrary. Any of the components described may be the first component, the second component, the third component or the fourth component. For example, a component that is referred to as a second component, may be the first component, the second component, the third component or the fourth component. The terms “encapsulate,” “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

According to Example 1, an integrated device includes a first die; a second die stacked above the first die and electrically interconnected to the first die; and a conductive structure in thermal contact with a top surface of the first die and in thermal contact with a top surface of the second die, the conductive structure configured to dissipate heat from the first die and the second die.

Example 2 includes the integrated device of Example 1, wherein the conductive structure includes a thermally conductive foil.

Example 3 includes the integrated device of Example 1 or Example 2, wherein the conductive structure has a ring shape that at least partially encircles the second die.

Example 4 includes the integrated device of any of Examples 1 to 3, wherein the conductive structure includes: a first piece attached to the top surface of the first die; and a second piece attached to the top surface of the second die and to the first piece.

Example 5 includes the integrated device of Example 4, wherein the first piece is attached to the second piece via one or more mechanical detents.

Example 6 includes the integrated device of any of Examples 1 to 5, wherein the first die includes an application processor, and wherein the second die includes a dynamic random-access memory.

Example 7 includes the integrated device of any of Examples 1 to 6, wherein the first die is included within a first package, wherein the second die is included within a second package, and wherein the first package and the second package are arranged in a package-on-package (POP) configuration.

Example 8 includes the integrated device of any of Examples 1 to 7, further including a first substrate that is electrically connected to the first die; a second substrate that is electrically connected to the second die; and electrical interconnects that form signal propagation paths between the first substrate and the second substrate.

Example 9 includes the integrated device of Example 8, wherein the conductive structure includes a conductive element that extends along a pathway between the first substrate and the second substrate that is devoid of the electrical interconnects.

Example 10 includes the integrated device of Example 8 or Example 9, wherein an arrangement of electrical contacts on a bottom surface of the second substrate matches an arrangement of the electrical interconnects.

Example 11 includes the integrated device of Example 10, wherein the electrical interconnects extend from the first substrate to the electrical contacts on the bottom surface of the second substrate to form the signal propagation paths without an intervening interposer substrate.

Example 12 includes the integrated device of any of Examples 1 to 11, wherein the conductive structure is in thermal contact with the top surface of the first die via a thermal interface material.

Example 13 includes the integrated device of any of Examples 1 to 12, wherein the conductive structure is in thermal contact with the top surface of the second die via a thermal interface material.

Example 14 includes the integrated device of any of Examples 1 to 13, further including an underfill layer that is disposed between a bottom surface of the second die and the conductive structure.

According to Example 15 a method of fabricating a package-on-package (PoP) device includes: attaching a first portion of a conductive structure to a top surface of a first die; positioning a second die above the first die; and attaching a second portion of the conductive structure to a top surface of the second die.

Example 16 includes the method of Example 15, further including: snapping the first portion to the second portion at one or more mechanical detents to form the conductive structure.

Example 17 includes the method of Example 15 or Example 16, wherein the first portion is attached to the top surface of the first die via a thermal interface material.

Example 18 includes the method of any of Examples 15 to 17, wherein the second portion is attached to the top surface of the second die via a thermal interface material.

According to Example 19, a device includes: an integrated device includes a first die; a second die stacked above the first die and electrically interconnected to the first die; and a first structure in thermal contact with a top surface of the first die and in thermal contact with a top surface of the second die, the first structure configured to dissipate heat from the first die and the second die; a printed circuit board (PCB) coupled to a bottom surface of the integrated device; and a second structure disposed above the integrated device and in thermal contact with the first structure, the second structure configured to dissipate heat from the device.

Example 20 includes the device of Example 19, wherein the first structure provides a thermal pathway from the first die and the second die to the second structure.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. An integrated device comprising:
a first die;
a second die stacked above the first die and electrically interconnected to the first die; and
a conductive structure in thermal contact with a top surface of the first die and in thermal contact with a top surface of the second die, the conductive structure configured to dissipate heat from the first die and the second die.

2. The integrated device of claim 1, wherein the conductive structure includes a thermally conductive foil.

3. The integrated device of claim 1, wherein the conductive structure has a ring shape that at least partially encircles the second die.

4. The integrated device of claim 1, wherein the conductive structure includes:
a first piece attached to the top surface of the first die; and
a second piece attached to the top surface of the second die and to the first piece.

5. The integrated device of claim 4, wherein the first piece is attached to the second piece via one or more mechanical detents.

6. The integrated device of claim 1, wherein the first die includes an application processor, and wherein the second die includes a dynamic random-access memory.

7. The integrated device of claim 1, wherein the first die is included within a first package, wherein the second die is included within a second package, and wherein the first package and the second package are arranged in a package-on-package (PoP) configuration.

8. The integrated device of claim 1, further comprising:
a first substrate that is electrically connected to the first die;
a second substrate that is electrically connected to the second die; and
electrical interconnects that form signal propagation paths between the first substrate and the second substrate.

9. The integrated device of claim 8, wherein the conductive structure includes a conductive element that extends along a pathway between the first substrate and the second substrate that is devoid of the electrical interconnects.

10. The integrated device of claim 8, wherein an arrangement of electrical contacts on a bottom surface of the second substrate matches an arrangement of the electrical interconnects.

11. The integrated device of claim 10, wherein the electrical interconnects extend from the first substrate to the electrical contacts on the bottom surface of the second substrate to form the signal propagation paths without an intervening interposer substrate.

12. The integrated device of claim 1, wherein the conductive structure is in thermal contact with the top surface of the first die via a thermal interface material.

13. The integrated device of claim 1, wherein the conductive structure is in thermal contact with the top surface of the second die via a thermal interface material.

14. The integrated device of claim 1, further comprising an underfill layer that is disposed between a bottom surface of the second die and the conductive structure.

15. A method of fabricating a package-on-package (POP) device, the method comprising:
attaching a first portion of a conductive structure to a top surface of a first die;
positioning a second die above the first die; and
attaching a second portion of the conductive structure to a top surface of the second die.

16. The method of claim 15, further comprising:
snapping the first portion to the second portion at one or more mechanical detents to form the conductive structure.

17. The method of claim 15, wherein the first portion is attached to the top surface of the first die via a thermal interface material.

18. The method of claim 15, wherein the second portion is attached to the top surface of the second die via a thermal interface material.

19. A device comprising:
an integrated device comprising:
a first die;
a second die stacked above the first die and electrically interconnected to the first die; and
a first structure in thermal contact with a top surface of the first die and in thermal contact with a top surface of the second die, the first structure configured to dissipate heat from the first die and the second die;
a printed circuit board (PCB) coupled to a bottom surface of the integrated device; and
a second structure disposed above the integrated device and in thermal contact with the first structure, the second structure configured to dissipate heat from the device.

20. The device of claim 19, wherein the first structure provides a thermal pathway from the first die and the second die to the second structure.
